(19) United States
(12) Patent Application Publication
(10) Pub. No.: US 2014/0182668 A1
(43) Pub. Date: Jul. 3, 2014

(54) HIGH EFFICIENCY SILICON-COMPATIBLE PHOTODETECTORS BASED ON GE QUANTUM DOTS AND GE/SI HETERO-NANOWIRES

(71) Applicants: Domenico PACIFICI, Providence, RI (US); Alexander ZASLAVSKY, Providence, RI (US); Son T. LE, Providence, RI (US)

(72) Inventors: Domenico PACIFICI, Providence, RI (US); Alexander ZASLAVSKY, Providence, RI (US); Son T. LE, Providence, RI (US)

(73) Assignee: BROWN UNIVERSITY, Providence, RI (US)

(21) Appl. No.: 14/093,938

(22) Filed: Dec. 2, 2013

Related U.S. Application Data
(63) Continuation of application No. PCT/US12/40809, filed on Jun. 4, 2012.
(60) Provisional application No. 61/492,589, filed on Jun. 2, 2011.

(51) Int. Cl. H01L 31/0352; H01L 31/075

(52) U.S. Cl. CPC H01L 31/035218; H01L 31/035227; H01L 31/075; B82Y 20/00
USPC 136/255; 257/16; 977/954

(57) ABSTRACT

The present disclosure focuses on Ge nanostructured materials for optoelectronic devices: including high-efficiency quantum dot (QD) photodetectors and Si and Ge heteronanowire solar cells. The common thread among these materials is the use of Ge/Si or Ge/oxide barriers to confine carriers and enhance photoconductive gain in detectors and optical absorption and spectral coverage in solar cells.

### CROSS REFERENCE TO RELATED APPLICATIONS

This application is a continuation of and claims benefit of priority to International Application No. PCT/US12/40809, filed Jun. 4, 2012, entitled “High-Efficiency Silicon-Compatible Photodetectors Based on Ge Quantum Dots and Ge/Si Hetero-Nanowires,” and U.S. Provisional Application No. 61/492,589, filed Jun. 2, 2011, entitled “High-Efficiency Silicon-Compatible Photodetectors Based on Ge Quantum Dots and Ge/Si Hetero-Nanowires,” the entire contents of which is incorporated herein by reference.

### STATEMENT REGARDING FEDERALLY SPONSORED RESEARCH OR DEVELOPMENT

This invention was made with support from Grant No. DMR-0520651 from the National Science Foundation, Grant No. DMR-0804915 from the National Science Foundation, and Grant U.S. DESC0001556 from the Department of Energy. The United States Government has certain rights in the invention.

### BACKGROUND

Optoelectronic devices such as photodetectors and solar cells are often fabricated in the semiconductor industry by depositing a sequential combination of thin layers of an oxide material, layers of semiconductor, and metals. The use of nano-scale materials such as quantum dots and nanowires for these devices adds novel physical properties which are not present in devices utilizing bulk materials.

Recently, silicon (Si) and germanium (Ge) quantum dots (QDs) have stimulated increased interest as viable material for high responsivity photodetectors in the visible and near infrared wavelength ranges. Silicon QD photodetectors have been shown to achieve relatively high responsivities, with peak values in the range 0.4-2.8 A/W, and optoelectronic conversion efficiencies as high as 200%. On the other hand, Ge QDs embedded in between silicon layers or in the gate dielectric on polycrystalline Si show much smaller responsivities, of the order of 10 mA/W in the visible to near-infrared range, and even smaller efficiencies (<0.1%) in the mid-infrared range. Incorporating Ge QDs in an insulating matrix such as SiO₂ allows for improved detectivity, however, the maximum responsivity values reported so far are 0.13 A/W at 820 nm (“A high efficiency 820 nm MOS Ge quantum dot photodetector”, IEEE Electron Dev. Lett. 24, 318 (2003) incorporated in its entirety by reference), and 1.8 A/W at 600 nm, with maximum peak efficiencies of up to 245% in the 400-600 nm range (“Enhanced 400-600 nm photoresponsivity of metal-oxide-semiconductor diodes with multi-stack germanium quantum dots”, Nanotechnology 19, 235203 (2008) incorporated in its entirety by reference).While these results are promising, only the incorporation of crystalline germanium quantum dots into devices has so far been reported (see also “Ge quantum dot tunneling diode with room temperature negative differential resistance” Appl. Phys. Lett. 97, 012101 (2010) incorporated in its entirety by reference). Also, the efficiency reported so far is very far from those achievable with other materials and design strategies, such as back-illuminated GaN/AlGaN heterojunctions reporting internal gain as high as 10³ and peak responsivity as high as 100 A/W in the wavelength range 343-365 nm. Finally, the reported devices typically rely on high temperature thermal treatments and fabrication techniques that are not amenable for easy, direct integration onto a silicon platform. Therefore, new approaches are required to improve the quantum efficiency of Ge-QD-based materials for photodetectors while keeping a high degree of compatibility with existing CMOS technology.

Similarly, investigation of the photoresponse of Ge nanowires is still in its infancy. The trapping/detrapping effects, the role of interfacial states, as well as the main photoconversion mechanisms are believed to be similar for both Ge quantum dots and nanowire systems. Although Si/Ge nanowire heterostructures have been previously investigated, the incorporation of these nanowires into efficient solar cell devices is still unexplored.

### SUMMARY

High-efficiency silicon-compatible optoelectronic devices based on Ge Quantum Dots and Ge/Si hetero-nanowires and their method of making and using are disclosed.

In one aspect, a photodetector device is provided having a photo-responsive layer; wherein the photo-responsive layer comprises an insulator with embedded amorphous germanium quantum dots.

In one or more embodiments, the insulator is a metal oxide.

In any of the preceding embodiments, the germanium quantum dots are between below 20 nm in diameter.

In any of the preceding embodiments, the photo-responsive layer comprises germanium quantum dots of density between 10¹⁷ and 10¹⁹ cm⁻³.

In any of the preceding embodiments, the photo-responsive layer comprises a layer with a thickness less than 300 nm.

In any of the preceding embodiments, the device can further include a transparent conducting layer positioned over and in electrical communication with an upper surface of the photodetector device; and a semiconductor substrate positioned under a lower surface of the photodetector device; and an electrical contact in electrical communication with the semiconductor substrate; wherein the quantum dots are in electrical communication with the substrate and the transparent conducting layer.

In any of the preceding embodiments, the substrate comprises silicon.

In any of the preceding embodiments, the transparent conducting layer comprises multiple layers.

In any of the preceding embodiments, the transparent conducting layer comprises an anti-reflection coating.

In any of the preceding embodiments, the transparent conducting layer comprises indium-zinc-oxide.

In another aspect, a method for fabricating a photodetector device is provided, including providing a semiconductor substrate; simultaneously co-sputtering a source of an insulator material and a source of germanium to form a photo-responsive layer comprising an insulator with embedded germanium quantum dots; depositing a transparent conductor layer over the photoresponsive layer; and forming an electrical contact between the germanium quantum dots and the transparent oxide layer.

In one or more embodiments, the substrate comprises silicon.

In any of the preceding embodiments, the insulator comprises a metal oxide.

In any of the preceding embodiments, the transparent oxide layer comprises indium-zinc-oxide.

In any of the preceding embodiments, the method includes maintaining the substrate at 400-800° C. during the deposition of the photo-responsive layer.

In any of the preceding embodiments, the method depositing the transparent conductor layer via sputtering.

In another aspect, the nanowire solar cell device include a plurality of vertically aligned heterogeneous photo-responsive nanowires, at least one nanowire having a top surface in electrical communication with a first transparent electrical contact and a bottom surface in electrical communication with a second electrical contact; wherein the nanowires comprise:
a germanium-based axially stacked pin junction comprising a p-doped layer and an n-doped layer with an intrinsic layer in between the n- and p-doped regions, and a silicon-based axially stacked pin junction comprising a p-doped layer and an n-doped layer with an intrinsic layer in between the n- and p-doped regions and, wherein the p-doped layer of the silicon-based pin junction is positioned adjacent to the n-doped layer of the germanium-based axial pin junction.

In one or more embodiments, the multitude of heterogeneous semiconductor nanowires are embedded in a transparent insulating layer wherein the top and bottom surfaces of the nanowire are exposed.

In any preceding embodiment, the transparent insulating layer comprises a metal oxide.

In any of the preceding embodiments, one or both of the electrical contacts comprise an transparent conductive oxide.

In any of the preceding embodiments, the transparent oxide comprises indium-zinc-oxide.

In any of the preceding embodiments, heterogeneous semiconductor nanowires are less than 300 nanometers in diameter.

In any of the preceding embodiments, heterogeneous semiconductor nanowires are more than 5 microns in length.

In any of the preceding embodiments, heterogeneous semiconductor nanowires are tapered in diameter along at least a portion of its length, forming a wider tapered end and a narrower tapered end.

In any of the preceding embodiments, the first electrical contact are in electrical communication with the wider tapered end of the nanowire.

In any of the preceding embodiments, the first electrical contact is in electrical communication with the narrower tapered end of the nanowire.

In another aspect, a method for fabricating a nanowire solar cell device is provided, including providing a heated semiconductor growth substrate, uniformly covered in growth seeds; simultaneously growing a multitude of vertically aligned heterogeneous semiconductor nanowires, one below each growth seed, the growth of each nanowire comprising the sequential steps of: exposing the growth seed to gases comprising germanium and p-doping precursor gases to grow a p-doped germanium nanowire layer, on the top surface of the semiconductor; exposing the growth seed to gases comprising a germanium precursor gas to grow an instrinsic germanium nanowire layer, on the p-doped germanium layer; exposing the growth seed to gases comprising germanium and n-doping precursor gases to grow an n-doped germanium nanowire layer, on the intrinsic germanium layer; exposing the growth seed to gases comprising silicon and p-doping precursor gases to grow a p-doped silicon nanowire layer, on the n-doped germanium layer; exposing the growth seed to gases comprising a silicon precursor gas to grow an instrinsic silicon nanowire layer, on the p-doped silicon layer; and exposing the growth seed to gases comprising silicon and n-doping precursor gases to grow an n-doped silicon nanowire layer, on the intrinsic silicon layer.

In one or more embodiments, the growth of layers involves tapering of the nanowire diameters along part of their length.

In any preceding embodiment, the sequence of nanowire layers is reversed.

In any preceding embodiment, the growth seeds comprise gold.

In any preceding embodiment, a nanowire has the same diameter as the growth seed.

In any preceding embodiment, growth seeds are less than 50 nm in diameter.

In any preceding embodiment, p-doped silicon and n-doped germanium semiconductor nanowire layers are less than 100 nanometers in combined thickness.

In any preceding embodiment, p-doped silicon and n-doped germanium semiconductor nanowire layers are greater than 10¹⁹ cm⁻³ in doping density.

In any preceding embodiment, the method includes etching away the growth seeds from the tops of the nanowires; embedding the plurality of nanowires in a transparent insulating material while leaving the top surface of the nanowire exposed; and removing the nanowires from the original growth substrate leaving the bottom surface of the nanowire exposed.

In any preceding embodiment, the method includes depositing a transparent electrical contact to at least one of the exposed nanowire surfaces.

In any preceding embodiment, the transparent insulating material comprises a metal oxide.

In any preceding embodiment, the metal oxide is synthesized via a sol-gel process.

In another aspect, a method of using a photodetector includes providing a photodector device comprising: a semiconductor substrate; and a transparent oxide layer; a photo-responsive layer comprising an insulator with embedded amorphous germanium quantum dots wherein the quantum dots are in electrical communication with the substrate and the transparent oxide layer; and an electrical contact in electrical communication with the semiconductor substrate; illuminating the photodetector; and measuring a subsequent change in voltage or current between the transparent conductive layer and the substrate.

In any preceding embodiment, the method includes illuminating the device in free space.

In any preceding embodiment, the method includes illuminating the device via a coupled waveguide.

In another aspect, a method of using a device includes providing a device as described hereinabove and exposing the device to a source of light with at least some of the light traveling parallel to the length of the nanowires through the first electrical contact; and harnessing a subsequent change in voltage or current between the two electrical contacts.

In another aspect, a heterogeneous photo-responsive nanowire includes a germanium-based axially stacked pin junction comprising a p-doped layer and an n-doped layer with an intrinsic layer in between the n- and p-doped regions, and a silicon-based axially stacked pin junction comprising a p-doped layer and an n-doped layer with an intrinsic layer in between the n- and p-doped regions and, wherein the p-doped layer of the silicon-based pin junction is positioned adjacent to the n-doped layer of the germanium-based axial pin junction.

The Ge quantum dot photodetector in the present disclosure has surprising responsivity and extremely high internal quantum efficiencies, and their simple fabrication and low thermal budget are fully compatible with on-chip integration. The solar cell device of this disclosure provides a broader absorption spectrum than available in Si bulk or nanowire devices, as well as reduced surface reflection.

### BRIEF DESCRIPTION OF DRAWINGS

FIG. 1 depicts a schematic of a high efficiency photodetector with embedded Ge quantum dots, according to an embodiment of the present disclosure.

FIG. 2 depicts a flow chart illustrating a method for producing high-efficiency photodetectors with embedded quantum dots, according to an embodiment of the present disclosure

FIG. 3 shows a schematic diagram of a ultra-high efficiency Ge quantum dot photodetectors integrated with Si-based waveguides.

FIG. 4 Depicts a graph comparing between I(V) curves in dark and under white light illumination for a photodetector with embedded quantum dots, according to an embodiment of the present disclosure. Inset: schematic of Ge QDs photodetector

FIG. 5A Depicts a graph of I(V) curves under monochromatic illumination of a photodetector device containing Ge QDs embedded in the insulator/silica layer, according to an embodiment of the present disclosure.

FIG. 5B Depicts a graph of I(V) curves under monochromatic illumination of a photodetector device without QDs (silica only), according to an embodiment of the present disclosure.

FIG. 6 Illustrates the possible mechanisms at work in the Ge QD photodetector, according to an embodiment of the present disclosure: (1) Photon absorption generates electron-hole pairs in Ge QDs. (2) Hopping of holes between contiguous QDs. (3) Tunneling of holes from QD region to metal. (4) Trapped electrons at QD/oxide interfacial states. (5) Injection of holes from the inversion layer, facilitated by trapped carriers.

FIG. 7A depicts plots of device responsivity the Ge QD photodetector under various reverse bias conditions (−2, −3 and −10 V), according to an embodiment of the present disclosure.

FIG. 7B depicts plots of experimental and simulated (FDTD and reflection model) reflectance of the the Ge QD photodetector at normal incidence, showing typical thin-film interference, according to an embodiment of the present disclosure.

FIG. 7C Depicts plots of internal quantum efficiency of the Ge QD photodetector as a function of wavelength for various bias voltages as indicated, according to an embodiment of the present disclosure.

FIG. 8A depicts plots of a FDTD calculations of the electric field intensity distribution vs wavelength (300-1100 nm) and depth (in the Ge QD photodetector), normalized by the field intensity of the incident wave, according to an embodiment of the present disclosure.

FIG. 8B depicts plots of the fraction of incident light intensity absorbed by the Ge QDs and by the first 4.5/u.m of silicon substrate (corresponding to the minority hole diffusion length), according to an embodiment of the present disclosure.

FIG. 9 depicts a schematic of a nanowire solar cell device, according to an embodiment of the present disclosure.

FIG. 10 depicts a flow chart illustrating a method for producing a nanowire solar cell device, according to an embodiment of the present disclosure.

FIG. 11A is a schematic illustration of the proposed tapered Ge/Si tandem pin hetero-nanowire for solar cell applications, according to an embodiment of the present disclosure. Sufficiently heavy doping at the n+-Ge/p+-Si heterojunction in the middle determines a low-resistance tunneling contact in reverse bias.

FIG. 11B shows a schematic diagram of tapered Si/Ge heteronanowire array for large area, high efficiency solar cells.

FIG. 12 depicts a schematic of a simulated pin Si nanowire section (inset) and a current versus voltage plot showing the response of the simulated pin Si nanowire section with D=50 nm and oxide-passivated interfaces, under 1 W/cm² illumination at X=500 nm, using Synopsys TCAD, according to an embodiment of the present disclosure. The i-sections of 150 and 650 nm produce different I_{Sc} values, whereas Vₒc˜0.6 V is in agreement with expected crystalline Si solar cell values.

FIG. 13A depicts a plot showing the I(V) characteristics of a rectifying p-Ge/i-Si/n-Si pin hetero-nanowire in the dark at T=300 K, with inset showing the device geometry (D˜40 nm, p doping of ˜1×10¹⁷ cm⁻³ and n doping ˜5×10¹⁸ cm⁻³), according to an embodiment of the present disclosure.

FIG. 13B depicts a plot of measured optical response of the p-Ge/i-Si/n-Si pin hetero-nanowire under laser illumination.

### DETAILED DESCRIPTION

Ge quantum dots embedded in silica matrix have attracted much attention in applied research for their interesting optoelectronic properties and the potential compatibility with the actual VLSI technology. The lower melting point temperature (973° C.) and the larger excitonic Bohr radius of Ge (˜24 nm) with respect to Si (1414° C., ˜5 nm respectively) allow for a lower fabrication temperature and a better modulation of the energy gap with the QDs size. In addition, the absorption coefficient of germanium is greater than silicon up to photon energies of about 4 eV.

Additionally, the physical mechanisms (for example those important in the operation of a specific device) benefit from the nanoscale size of the Ge active regions as described in this disclosure, whether through carrier confinement in real space or through the momentum-space modification of the dispersion relations.

The present disclosure focuses on Ge nanostructured materials for optoelectronic devices: including high-efficiency quantum dot (QD) photodetectors and Si and Ge heteronanowire solar cells. The common thread among these materials is the use of Ge/Si or Ge/oxide barriers to confine carriers and enhance photoconductive gain in detectors and optical absorption and spectral coverage in solar cells.

In one aspect, Ge-based materials are fabricated using selective oxidation of sputter-deposited Ge QDs in an insulating, e.g., oxide, matrix. The Ge-based QD devices include metal/insulator/semiconductor (MIS) photodetectors with Ge QDs embedded in an insulating matrix, which have enhanced quantum efficiency and high responsivity (i.e. operation at a relatively low reverse bias) and a broad, flat spectral response in the visible to near-infrared wavelength range. In one or more embodiments, it exhibits an internal quantum efficiency (IQE) of about 700% in a broad wavelength range between 450 nm and 1000 nm.

In another aspect, Ge-based broad-spectrum tandem solar cells are disclosed. In some embodiments, the Ge-based solar cells include Ge-based nanowires of diameter D<50 nm prepared by VLS (vapor liquid solid) growth. By virtue of their narrow D during growth, the lattice mismatch strain can be alleviated by lateral sidewall expansion, making it possible to insert a high Ge content (or even pure Ge) section in the nanowire, which is not possible in planar epitaxy without generating dislocations. The Si/Ge hetero-nanowires employ axial doping control to provide heterojunctions for optoelectronic activity. The availability of low strain hetero Si/Ge nanowires provide new capabilities in barriers and quantum wells in both valence and conduction band. This enables previously impossible tandem Ge/Si solar cell materials, where a series combination of Ge and Si axial pin diodes with an internal tunneling contact are used in a hetero-nanowire array broad-spectrum solar cell (broader absorption spectrum than available in Si nanowires alone), leading to higher open-circuit voltage and efficiency, as well as reduced surface reflectivity.

The fabrication approaches for both devices, as well as the target materials, are compatible with the dominant silicon technology which is currently expanding to include both alternative active materials (i.e. Ge in certain embodiments), and to the on-chip integration of detectors. Thus, the Ge active materials described in this disclosure utilize Si or silicon-on-insulator (SOI) substrates, standard fabrication steps with reasonable thermal budgets, and target room-temperature operation.

The Ge-based quantum dots and Ge-based heteronanowires can be used a optical electronic materials in solar cells, optical sources, and photodetectors or sensors, in the scientific, commercial and military market segments. These devices find application in industries including the computer/microelectronics, e.g., wafer bonding, and solar cell energy panel, among many others using photodetectors, optics and/or sensors.

### Ge Quantum Dots (QD) for High-Efficiency Photodetectors (PD)

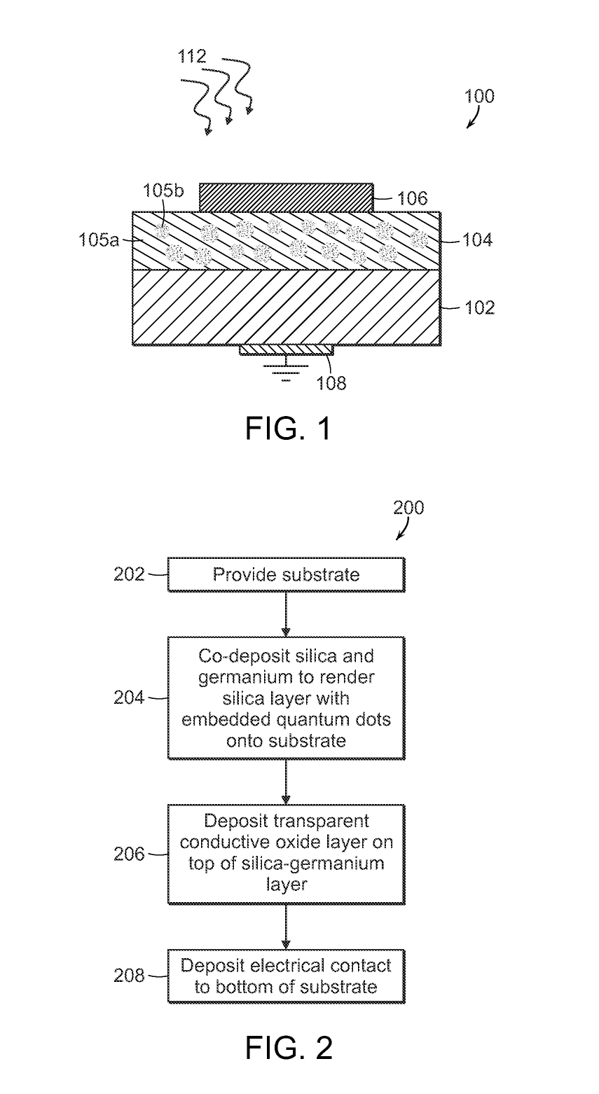

An exemplary photodetector device 100 is shown in FIG. 1. This metal-insulator-semiconductor (MIS) photodetector (PD) device 100 includes a substrate 102, a photo-responsive layer 104 with an insulating matrix 105a and embedded amorphous germanium quantum dots 105b, a transparent conductive layer 106, and an electrical contact 108. The photo detector operates by converting light signals 112 that illuminate the photo-responsive layer 104 to a voltage or current.

The substrate 102 is provided and has a top and bottom surface. In certain embodiments, the substrate 102 can be silicon or other semiconductor material. In certain embodiments, the substrate includes an n-type silicon substrate.

The germanium quantum dots in the photo-responsive layer 104 are in electrical communication with the substrate 102. In this disclosure, the term electrical communication includes either direct electrical contact leading to a current or indirect electrical contact resulting in an electron tunneling current. The photo-responsive layer 104 consists of an insulating matrix with a high-density of embedded amorphous germanium quantum dots (QD). Amorphous quantum dots provide several advantages over crystalline quantum dots, specifically a higher absorption coefficient, a broader spectral response, and low temperature synthesis. In certain embodiments, the photo-responsive layer includes germanium quantum dots between about 2 nm to about 20 nm , or about 2 nm to 10 nm, or about 2 nm to 5 nm or about 2 nm to 3 nm, or less than 20 nm in diameter and a density ranging from 10¹⁷ to 10¹⁹ cm⁻³. The size and distribution of quantum dots can be used to control absorption and internal gain mechanisms. The insulating matrix can be any insulating materials commonly used in the photooptics or semiconducting industries. By way of example, the insulating matrix can include silica (SiO₂) layer or other oxides, specifically dielectrics with a high dielectric constant, e.g., or other metal oxides and high k dielectric materials. In certain embodiments, the photo-responsive layer includes a layer <300 nm thick. The layer thickness can be used to control the speed of response of the device but must be optimized for specific applications as thinner layers lead to faster response but reduced sensitivity. In certain embodiments, the thickness of the photoactive layer is less than 300 nm, or less than 250 nm, less than 200 nm, less than 150 nm, less than 100 nm or less than 50 nm.

The transparent conductive layer 106 is positioned in electrical communication with the photo-responsive layer. In certain embodiments, the transparent conductive layer is a transparent conductive oxide such as indium-tin-oxide (ITO), zinc-doped indium oxide, aluminum-doped indium oxide, cadmium-doped indium oxide by way of example. Other transparent conductors can be used as is understood by those skilled in the art. The thickness of the transparent conductive layer may be tuned for sensitivity and absorption at different wavelengths. It may also consist of a plurality of conductive layers. The transparent conductive layer may even be utilized to create an anti-reflective coating on the device. In certain embodiments, the transparent oxide layer includes a layer between about 50 nm and about 100 nm in thickness, or less than 100 nm, less than 90 nm, less than 80 nm, less than 70 nm, less than 60 nn.

The electrical contact 108 is positioned in electrical communication with semiconductor substrate 102. The electrical contact can be any conductive material and can be materials available as ohmic contacts. In one or more embodiments, the electrical contact is a metal, for example silver paste. The contact can be sputtered or evaporated metal contacts that are patterned for example using photolithography.

In some embodiments, a voltage is applied to the device and the resulting current produced by the device is measured between the transparent conductive layer 106 and the bottom contact 108, upon light illumination 112 from the top.

Another aspect of the present disclosure is the method 200 of fabricating a photodetector (FIG. 2). The method includes the steps of providing a semiconductor substrate 202, depositing a photo-responsive layer 204, and depositing a transparent oxide layer 206.

In certain embodiments, the semiconductor substrate 202 is silicon, or more specifically an (100) n-type silicon (n-Si) substrate.

In order to obtain a well distributed population of amorphous Ge QDs in an insulating matrix, silica and germanium can be co-deposited on the semiconductor substrate to provide an amorphous mixed metal oxide layer, followed by heat treatment to form nanoscale domains of germanium, i.e., Ge QDs. The heat treatment is conducted at a temperature that is sufficient to cause nucleation of Ge nanoscale domains, but sufficiently low to avoid crystallization of the Ge-domains. The low temperature deposition provide amorphous Ge QDs, which have been demonstrated to possess a higher absorption coefficient and a broader spectral response than crystalline silicon or germanium quantum dots. In addition, the low temperature conditions are compatible with the dominant silicon technology. Depositing a photo-responsive layer 204 can be achieved by simultaneously co-sputtering silica and germanium on the semiconductor substrate to form a photo-responsive layer comprising silica with embedded germanium quantum dots. In some embodiments, the photo-responsive layer deposition 204 includes rf-magnetron co-sputtering from a SiO₂ and a Ge target onto the semiconductor substrate. In certain embodiments, the method 200 includes maintaining the semiconductor substrate 202 at 400-800° C., preferably between 400-500° C., during deposition of the photo-responsive layer 204. The deposition process can be conducted in vacuum. Higher temperature post-processing (for example annealing) may also be performed. Deposition and processing factors tuned the affect the size and density of the resulting germanium quantum dots, including: (1) The relative ratio of silica and germanium sputtered into the layer, (2) the temperature of the substrate during deposition, and (3) the post-processing/annealing temperature.

In some embodiments, the device is completed by providing electrical contacts for completing the circuit. A transparent conductive oxide layer 206 is deposited onto the photo-responsive layer 204 using sputtering or other conventional techniques. The transparent oxide layer 206 can be indium-zinc-oxide or other transparent conductors as are known in the art. In certain embodiments, the method 200 includes applying a metal or electrical contact to the bottom surface 208 of the semiconductor substrate. The metal contact can be a grounded metal contact as illustrated in FIG. 1.

In one embodiment, Ge QDs embedded in a silica matrix have been realized by sputter deposition of a thin film of SiGeO on an n-type Si substrate, by magnetron co-sputtering of SiO₂ and Ge targets. The relatively low substrate temperature of 400° C. during the deposition was high enough to allow for the nucleation of small amorphous Ge QDs with a size of about 2-3 nm (due to the precipitation of excess Ge) in as-deposited samples. In some embodiments, the deposition method did not require additional high-temperature processing of the device for optimal operation and therefore allowed for improved compatibility with conventional microelectronics processing. This aspect provided an advantage over more difficult methods for low-temperature device integration on a silicon platform, such as wafer bonding.

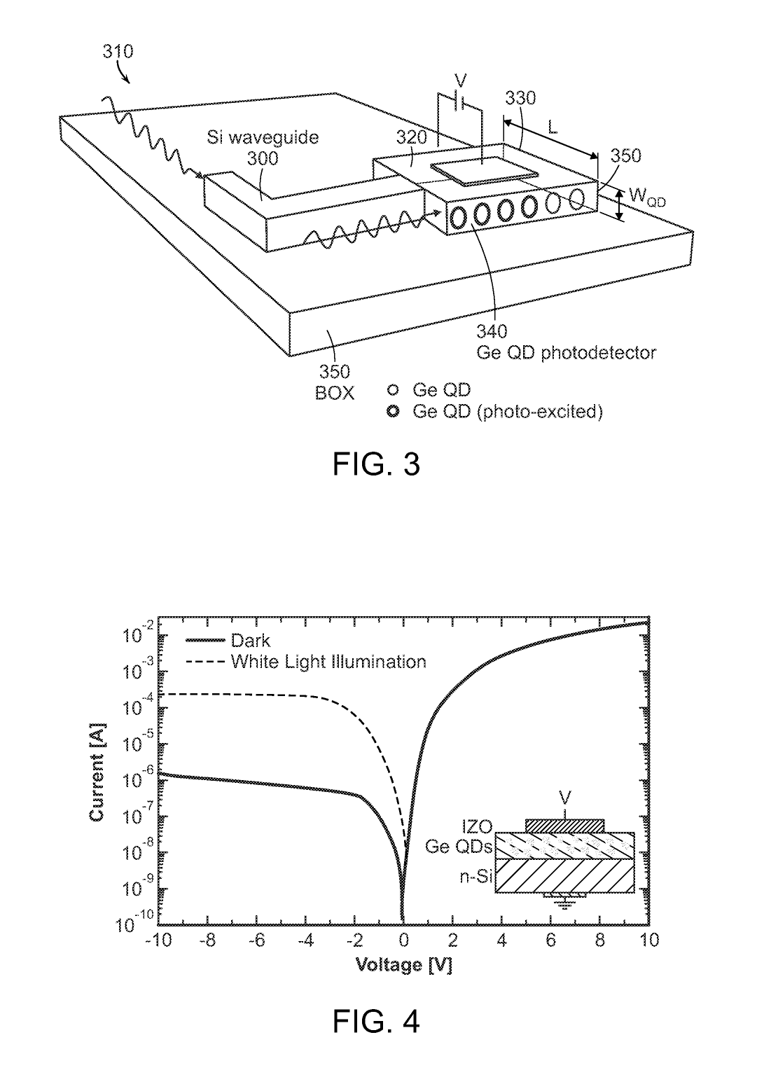

In some embodiments, the photodetector device can be operated as shown in FIG. 3. In this diagram, a Si waveguide 300 is used to guide light 310 into the photodetector 320 that includes a photoactive layer 330 containing a-Ge quantum dots 340 embedded in an insulating matrix 350. A voltage V is established at the detector between the top metal contact and the substrate 350, and a resulting current can also be measured between the same contacts. Bright outlines indicate photoexcitation of the Ge QDs.

In one embodiment, the exemplary Ge QD-based photodetector has yielded responsivity of up to 4 A/W at 900 nm and internal quantum efficiencies >100% in a very broad spectral range, from 450-1000 nm, with peak efficiencies as high as 550% at 900 nm and 700% at 700 nm. These high quantum efficiencies were the result of a non-linear internal gain mechanism. The incorporation of high density of nanometer-size amorphous Ge QDs in the SiO₂ layer provides an efficient photoelectric response.

FIG. 4 shows a comparison between the I(V) curves in dark condition and under white light illumination for the as-deposited sample, corresponding to the schematic picture of a certain embodiment of a MIS structure in the inset. The I(V) in dark condition showed a rectifying behavior, with a small current under reverse bias and an exponential increase of current under forward bias. This is typical for MIS devices on an n-type semiconductor substrate, in which majority carriers (electrons) contribute to the current for forward applied bias while for reverse bias the current is due to the minority carriers (holes). When the sample was exposed to white light illumination, reverse current increased by more than two orders of magnitude due to the contribution of photo-generated carriers, while the forward current was largely unaffected. In order to understand the mechanism of photo-induced conduction, I(V) measurements were performed by illuminating the device with various incident wavelengths λ.

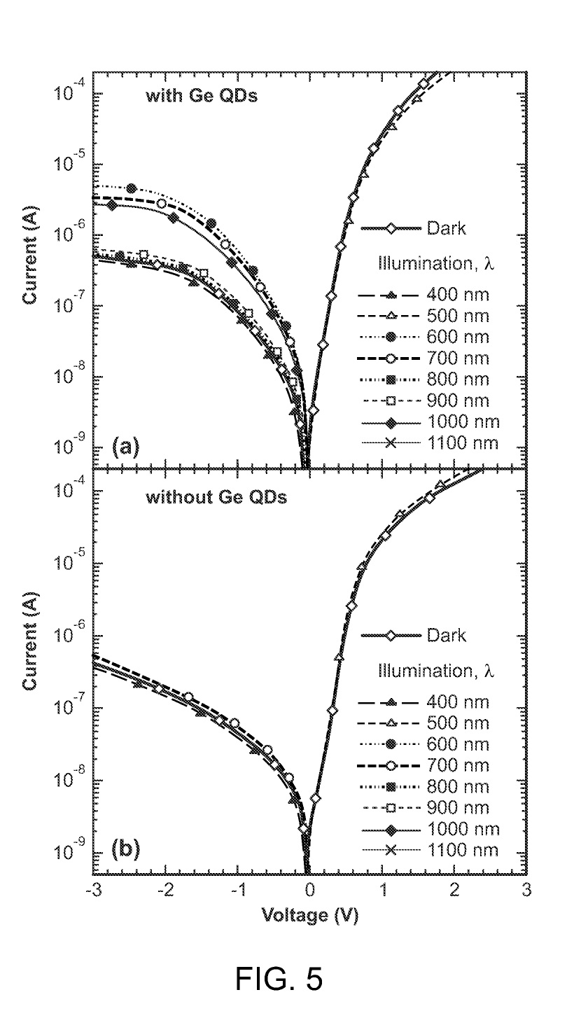

The top panel of FIG. 5 shows I(V) curves for the same device embodiment as above containing Ge QDs under illumination with different wavelengths in the 400-1100 nm range, indicating the wavelength dependence of carrier photogeneration. Control samples were also fabricated with same oxide thickness, on the very same substrate, but lacking Ge QDs. The I(V) curves of this device, shown in the bottom panel of FIG. 5, exhibited no photocurrent regardless of illumination, manifesting the fundamental role of Ge QDs in the photo-generation process.

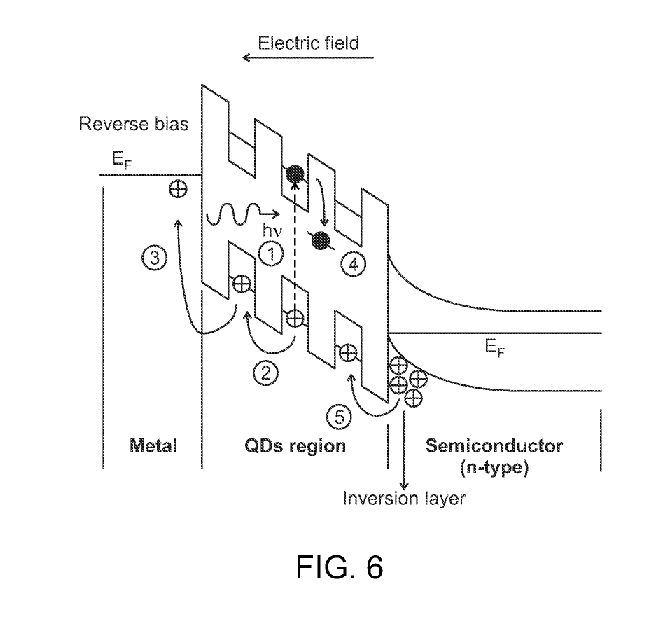

In general and while not being bound by any particular mode of operation, there are various mechanisms at work that could be responsible for the observed currents and photoresponse. A possible explanation of the various mechanisms at work in the same device embodiment as above is illustrated in FIG. 6. In the dark, the contribution to the current is related to the holes formed in the inversion layer between the interface of the semiconductor and the oxide barrier. These holes could tunnel through the oxide barrier. A second contribution is attributable to the photo-carriers generation when photons with energy greater than the bandgap of Si (1.12 eV) are absorbed in the depletion region. The photo-generated holes can reach the inversion layer by diffusion and tunnel through the oxide barrier via the electronic states of Ge QDs. In addition, other electron-hole pairs can be formed if the applied bias is high enough to ensure a hot-carrier generation process. A final contribution to the reverse bias current is related to the electron-hole pair formation when incident photons are absorbed by Ge QDs. Also in this last case, if the applied bias is high enough, impact ionization processes become possible that could create additional electron-hole pairs in nearby Ge QDs. Tests of a specific embodiment of the device in FIG. 1 imply that Ge QDs are important to observe the photocurrent, which implies exciton generation by photon absorption, electron trapping, and consequent hole transport by hopping or percolation as a sound mechanism to explain the observed photocurrent.

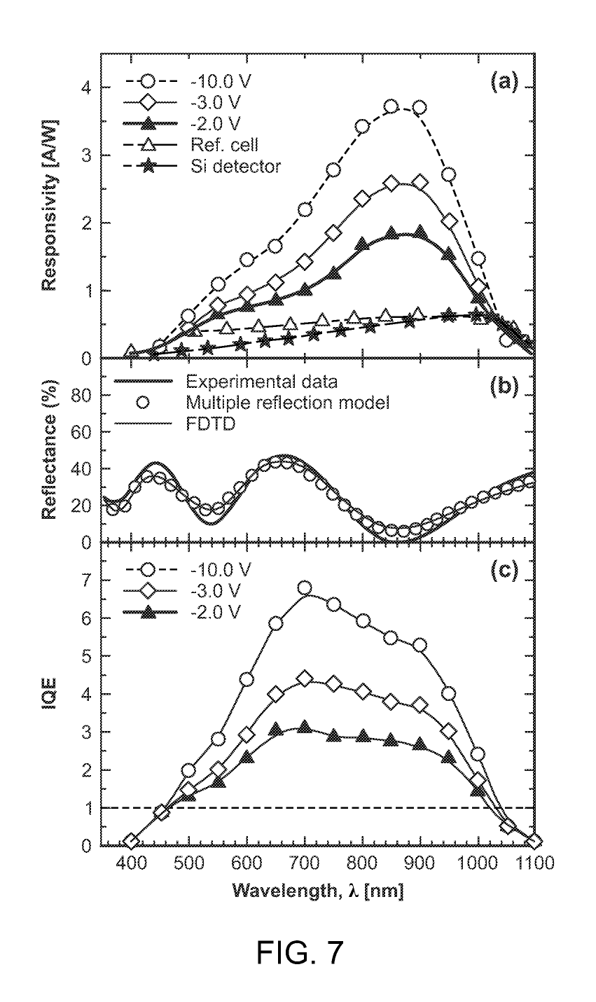

FIG. 7A shows the spectral responsivity of a specific embodiment of the device in FIG. 1 (containing Ge QDs) as a function of wavelength in the range 350-1100 nm, obtained by measuring the photogenerated current (defined as the difference between the total current under illumination conditions minus the dark current) and normalizing it to the incident optical power. A clear peak was observed at λ˜900 nm, with responsivity as high as 4 A/W at −10.0 V bias. These responsivities were more than 40 times higher than any reported values for Ge QDs, and more than a factor 4 higher than commercially available devices. Such high responsivities suggest the potential for very compact detectors that could be integrated on-chip. The flux of photons incident on the sample surface was measured by using a calibrated detector with responsivity of 0.5 A/W at 900 nm, showing that the number of photons per unit time varied from 2×10¹²/s to 1.3×10¹³/s in the 400-1100 nm range. The spectrally-resolved internal quantum efficiency (photogenerated carriers divided by the number of incident photons) was then calculated by measuring the specular reflectance R at normal incidence, shown in FIG. 7B, and then normalizing the number of photogenerated carriers by (1-R) and by the number of incident photons incident on the sample surface at each wavelength. The results were summarized in FIG. 7C, and show internal quantum efficiencies as high as 700% at −10 V reverse bias, corresponding to as many as 7 carriers generated by a single incident photon. In certain embodiments this intriguing gain mechanism can be investigated.

Furthermore, the data in FIG. 4 also suggest that upon illumination, an open circuit voltage of ˜0.2V was established in the MIS structure, suggesting a photovoltaic effect induced by the incident white light. In some embodiments, the high internal gain mechanism can be exploited to investigate sputtered Ge QDs as an active material for photovoltaics. The broadband spectral responsivity indicates strong potential of the fabricated material for broadband absorption of incident photons, and improved external quantum efficiency in an appropriately designed solar cell.

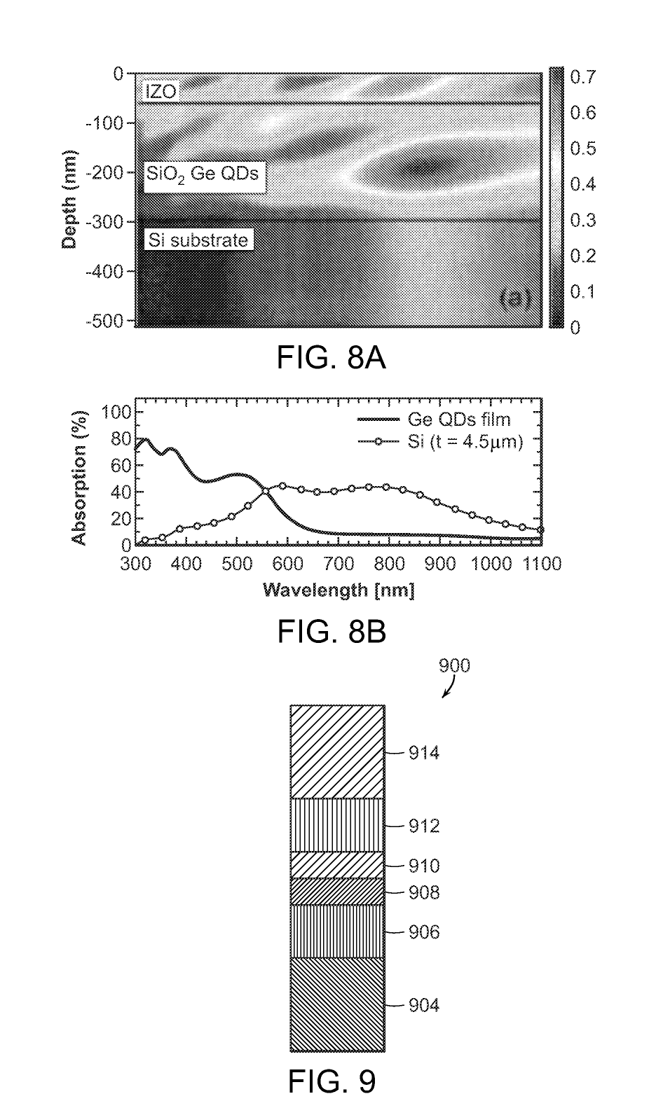

Finite-difference-time-domain (FDTD) calculations were performed using a commercial software (LUMERJ-CAL) to reproduce the reflectance measurements [seen in FIG. 7B] and to calculate the electric field intensity distribution inside the PD structure, as shown in FIG. 8A, as a function of λ and depth. At 900 nm, the electric field intensity (normalized to the incident field intensity) peaked inside the insulating layer containing the Ge QDs, although there was also leakage of incident radiation into the Si substrate. From the simulations and definition of the Poynting vector, fraction of absorbed light intensity occurring within the Ge QDs and the silicon substrate, respectively, were estimated the as shown in FIG. 8B. The results show that while shorter wavelengths were absorbed mostly in the Ge QDs, longer wavelengths were preferentially absorbed in the bulk Si. However, only the photogenerated holes that were created within a minority carrier diffusion length of the interface (˜4.5 μm for our n-Si substrate) tunneled into the Ge QDs, where they became trapped and induced the electron flow, leading to the observed photocurrent. These results demonstrated that light absorption by Ge QDs [which have an optical band gap of 1.6 eV (Ref 8)] and in the silicon substrate were crucial for achieving a broad spectral response. In some embodiments, further studies clarify the details of the photoconductive gain mechanisms and transport via photoexcited Ge QDs.

In certain embodiments, a device and method for fabricating MIS PDs containing a-Ge QDs in the SiO₂ insulator that operate in the visible and near-infrared with high IQE (up to ˜700%) and have responsivity up to 4 A/W were demonstrated. These devices were shown to be operated at a reverse bias as low as 2 V and were fabricated with processing steps below 400° C. Their high efficiency was attributed to photoconductive gain provided by the trapping of holes in the Ge QDs. These findings open a route toward the realization of high-efficiency PDs based on Ge QDs that are easily integrated into a standard silicon complementary metal-oxide semiconductor process.

Ge/Si Heteronanowires (nanowire) for Solar Cells

In another aspect, a different class of materials for optoelectronic devices includes VLS (vapor-liquid-solid method)—grown narrow Si/Ge hetero-nanowires with axial pin junctions for either broad-spectrum absorption. A pin junction consists of three adjacent differently doped semiconductor layers: an intrinsic or undoped layer sandwiched between a p- and an n-doped layers. In the former case, what is required for certain embodiments is an array of hetero-nanowires with separate pin Ge and Si sections, and sufficient doping control to permit a low-resistance np tunneling contact between the sections.

In VLS epitaxy, a seed (usually liquid gold, Au) catalyzes 1D (one-dimensional) growth. Developed decades ago for growth of single-crystal whiskers, it has recently been adapted to nanowires by using very small seeds. The insertion of heterostructures into these ID nanowires soon followed.

VLS SiGe/Ge heteronanowire growth can proceed as follows: the process begins with using an Au cluster as a seed and a growth substrate (typically Si). The Au seed provides a clean surface underneath the Au/Ge eutectic and determines the diameter of the resulting nanowire. The precursor gases such as SiH₄ as a silcon source and GeH₄ as a germanium source are injected into the system and adsorbed onto the Au, releasing H₂; the Ge or Si incorporates into the melt, diffuses to the liquid-solid interface and recrystallizes as a crystalline SiGe layer. Changing the precursor gas can provide an abrupt change in composition in the axial direction. For example, the flow of GeH₄ can be stopped and a flow of pure SiH₄ results in the adsorption of silicon only onto the Au seed. The silicon diffuses to the liquid-solid interface and recrystallizes as a crystalline Si layer. Repeated cycles of adsorption and growth result in multi-layered Si/Ge heteronanowires. The growth seed at the top surface of the nanowire is a by-product of the synthesis method and some embodiments comprise removing the growth seed before the nanowire is rendered operational. Ideally, little or no growth occurs except underneath the Au/semiconductor eutectic. Further details on VLS deposition, generally, is found at “Vapor-liquid-solid mechanism of single crystal growth”, Appl. Phys. Lett. 4, 89 (1964), which is incorporated herein by reference.

The following sections describe methods and devices which incorporate VLS epitaxy.

An exemplary heterogeneous photo-responsive nanowire 900 is shown in FIG. 9.

The heterogeneous photo-responsive nanowire 900 includes layers of p-doped germanium 904, intrinsic germanium 906, n-doped germanium 908, p-doped silicon 910, intrinsic silicon 912, and n-doped silicon 914.

The heterogeneous photo-responsive nanowire 900 includes a germanium axial pin junction comprising a layer of p-doped germanium 904 and a layer of n-doped germanium 908 with a layer of intrinsic germanium 906 in between the n- and p-doped regions, and a silicon axial pin junction, comprising a layer of p-doped silicon 910, a layer of n-doped silicon 914, and a layer of intrinsic silicon in between the n- and p-doped regions 912, wherein the p-doped layer of the silicon pin junction 910 is positioned adjacent to the n-doped layer of the germanium axial pin junction 908.

In some embodiments, the heterogeneous photo-responsive nanowire 900 may be less than 300 nanometers in diameter and greater than 5 microns in length. By virtue of such narrow diameters during growth, the lattice mismatch strain is alleviated by lateral sidewall expansion, making it possible to insert a high Ge content (or even pure Ge) sections in the NW, which is not possible in planar epitaxy without generating dislocations.

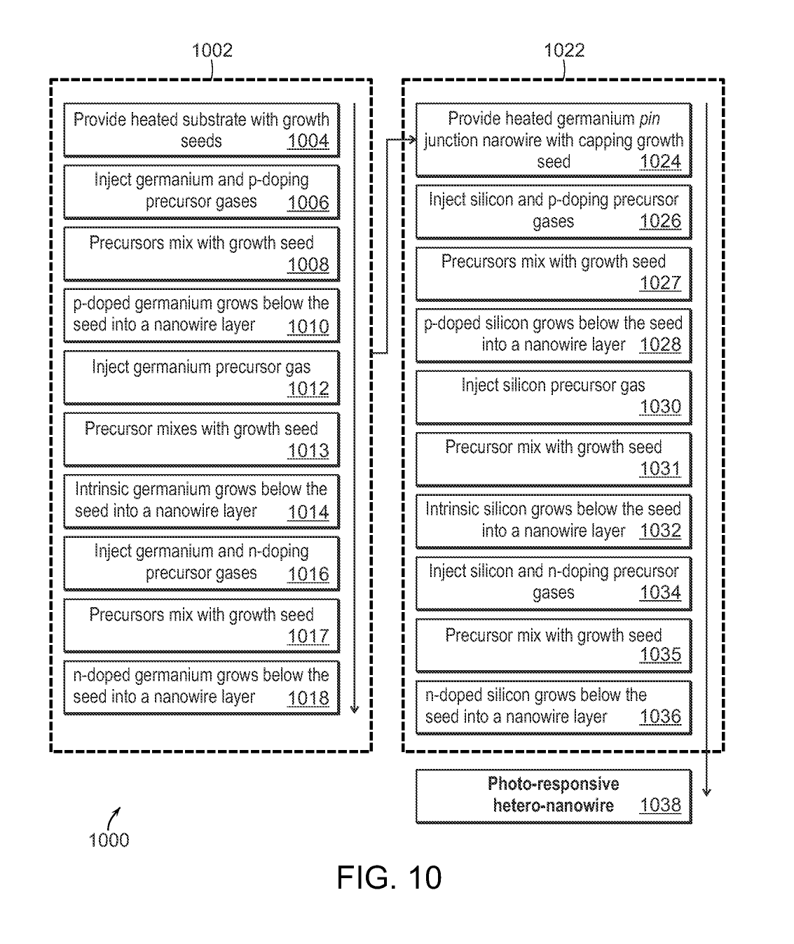

Another aspect of the present disclosure is the method 1000 of fabricating a heterogeneous photo-responsive nanowire as shown in FIG. 10. Fabrication of a nanowire cell device 1000 takes place in a closed environment. The method includes the steps of fabricating a germanium pin junction nanowire 1002, comprising: providing a semiconductor substrate 1004, injecting gases comprising germanium and p-doping precursor gases 1006, mixing the germanium and p-doping precursor gases with the growth seed 1008, growing a p-doped germanium nanowire layer 1010, injecting gases comprising a germanium precursor gas 1012, mixing the germanium precursor gas with the growth seed 1013, growing an instrinsic germanium nanowire layer 1014, injecting gases comprising germanium and n-doping precursor gases 1016, mixing the germanium and n-doping precursor gases with the growth seed 1017, and growing an n-doped germanium nanowire layer 1018; and fabricating a silicon pin junction nanowire 1022, comprising: providing a substrate 1024, injecting gases comprising silicon and p-doping precursor gases 1026, mixing the silicon and p-doping precursor gases with the growth seed 1027, growing a p-doped silicon nanowire layer 1028, injecting gases comprising a silicon precursor gas 1030, mixing the silicon precursor gas with the growth seed 1031, growing an instrinsic silicon nanowire layer 1032, injecting gases comprising silicon and n-doping precursor gases 1034, mixing the silicon and n-doping precursor gases with the growth seed 1035, and growing an n-doped silicon nanowire layer 1036; rendering a nanowire solar cell device 1038.

For GeH₄ germanium precursor gas, B₂H₆ and PH₃ can be used as p- and n-type dopants, respectively (as seen in, “Growth, electrical rectification and gate control in axial in-situ doped p-n junction Ge nanowires”, Appl. Phys. Lett. 96, 262102 (2010), which is incorporated herein by reference)

In certain embodiments, fabrication of a nanowire cell device 1000 includes applying a metal contact to the bottom surface of the semiconductor substrate. The metal contact can be grounded.

Providing a substrate 1004 is achieved by heating the semiconductor substrate uniformly covered in growth seeds, the substrate having a top surface and a bottom surface. In certain embodiments, the growth seeds comprise gold. In certain embodiments, the growth seeds comprise growth seeds of less than 50 nm in diameter. In certain embodiments, the semiconductor substrate 1004 includes silicon.

Fabricating a germanium pin junction nanowire 1002 can include injecting gases comprising germanium and p-doping precursor gases 1006, into the system, mixing the germanium and p-doping precursor gases with the growth seed 1008 to grow a p-doped germanium nanowire layer 1010 on the top surface of the semiconductor substrate and below the seed; injecting gases comprising a germanium precursor gas 1012, into the system, mixing the germanium precursor gas with the growth seed 1013 to grow an instrinsic germanium nanowire layer 1014, on the p-doped germanium layer and below the seed; injecting gases comprising germanium and n-doping precursor gases 1016, into the system, mixing the germanium and n-doping precursor gases with the growth seed 1017 to grow an n-doped germanium nanowire layer 1018, on the intrinsic germanium layer and below the seed. In one or more embodiments, the heteronanowire is greater than 5 μm, or greater than 10 μm, or greater than 15 μm or greater than 20 μm and can be up to 100 μm in length. The various layers within the nanowire will vary in thickness depending on their function. For example, p⁺n⁺ contact are relatively thin and can be less than 100 or 200 nm in thickness. In contrast, the the n-Si, i-Si, i-Ge, and p-Ge layers are relatively thick and can be greater than 200 nm, greater than 1 μm, greater than 5 μm, greater than 100 μm or greater than 300 μm.

A silicon pin junction nanowire is deposited on top of the germanium pin junction nanowire, as illustrated in step 1022, by injecting gases comprising silicon and p-doping precursor gases 1026, into the system, mixing the silicon and p-doping precursor gases with the growth seed 1027, growing a p-doped silicon nanowire layer 1028, on the n-doped germanium layer and below the seed; injecting gases comprising a silicon precursor gas 1030, into the system, mixing the silicon precursor gas with the growth seed 1031, growing an instrinsic silicon nanowire layer 1032, on the p-doped silicon layer and below the seed; injecting gases comprising silicon and n-doping precursor gases 1034, into the system, mixing the silicon and n-doping precursor gases with the growth seed 1035, and growing an n-doped silicon nanowire layer 1036, on the intrinsic silicon layer and below the seed.

In some embodiments, fabrication of a nanowire cell device includes semiconductor nanowire layers 100-200 nanometers in thickness

In some embodiments, fabrication of a nanowire cell device includes applying a metal contact to the top of the nanowire.

In some embodiments, fabrication of a nanowire cell device includes a nanowire having the same diameter as the growth seed.

In some embodiments, fabrication of a nanowire cell device includes reversing the sequence of nanowire layers.

Once grown, the array or nanowires can be stabilized or mechanically strengthened by embedding in an insulating matrix. The array of nanowires/insulating matrix can be obtained by depositing a thick SiO₂ layer over the nanowires and etching back to reveal the tops of the nanowires. Electrical contact can be made with the embedded nanowires, for example, by laying down a conductive metal layer by evaporation or sputtering deposition methods. An exemplary metal includes nickel (Ni).

Conversely, individual wires can be dispersed on a SiO₂ covered Si substrate and contacted and gated via e-beam lithography and metal (nickel) silicide formation, as shown in FIG. 16 inset.

The hetero-nanowires can be further treated past fabrication, for example the nanowires can be passivated and/or slimmed in D (diameter) by repeated oxidation and etching.

The germanium and silicon domains resulting from VLS fabrication can range in composition from a Si/Ge mixture up to pure germanium or silicon respectively. The Ge content of SiGe nanowires can be increased by high-temperature oxidation, where Si goes preferentially into the oxide—nearly pure Ge nanowires can therefore be produced.

The heteronanowire samples in the Si/Ge system can be grown in a state-of-the-art LPCVD systems such as those available in the group of S. T. Picraux at Los Alamos National Laboratory.

The VLS technique can be employed to fabricate Si or Ge nanowires, as well as axial or core/shell Si/Ge hetero-nanowires in the D<50 nm range. The wire length is controlled by growth time, so nanowires which are several μm long can be grown. Heterostructures can be inserted in the wire by changing the source gas. Excellent abruptness of the heterostructure layers in VLS-grown wires has been demonstrated in III-V materials, and recently abrupt axial junctions in VLS-grown Si/Ge hetero-nanowires have been reported as well (“Formation of compositionally abrupt axial heterojunctions in silicon-germanium nanowires”, Science 326, 1247 (2009) which is incorporated herein by reference).

The resulting nanowires can be single-crystal, with few defects except at the original Si interface.

In a certain embodiment, an array of such hetero-nanowires as described above illuminated from the top, partially absorbs wavelengths shorter than λ˜1.1 um by the Si pin diode, whereas the Ge pin diode absorbs the additional 1.1<λ<1.9 um spectral range (as well as part of the λ<1.1 μm radiation not absorbed in the Si). It is important to note that such a Ge/Si tandem cannot be fabricated by planar epitaxy due to lattice mismatch, but is produced by VLS growth in a manner similar to the hetero-nanowire as described above.

In a specific embodiment where the hetero-nanowire material consists of a Si axial pin junction grown on top of a Ge pin junction, itself grown on a Si (111) substrate, the heavy doping in the n-Si/p-Ge junction ensures a low-resistance tunneling contact and the i-Ge and i-Si regions are scaled to ensure approximate short-circuit current Isc match under solar illumination.

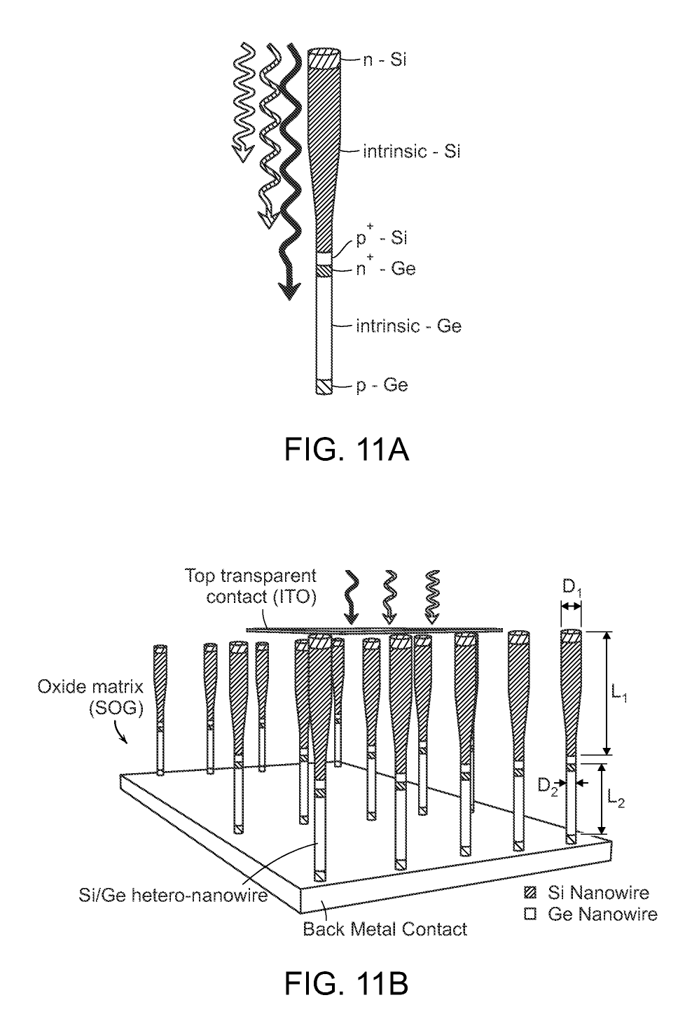

An example of a Ge/Si hetero nanowire for solar cell applications is shown schematically in FIG. 11A. The naturally occurring tapering effect in the nanowires can be used to enhance the optical absorption and overall external quantum efficiency of the tandem Si/Ge hetero-nanostructure solar cell.

Arrays of Si, Ge, and Si/Ge hetero-NWs can be grown on silicon-on-insulator using VLS epitaxy. After growth, the residual Au tip (growth seed) can be removed by chemical etching and the remaining array embedded in a thick spin-on-glass matrix (or other sol gel material precursors). The embedded array can then be stripped off the substrate, transparent metal contacts deposited on both sides and the array performance measured by exposing the wider and slimmer tips of the tapered wires to the incident radiation, to study the waveguiding effects induced by the tapered geometry as a function of taper angle, width and wire length (as shown in FIG. 11B).

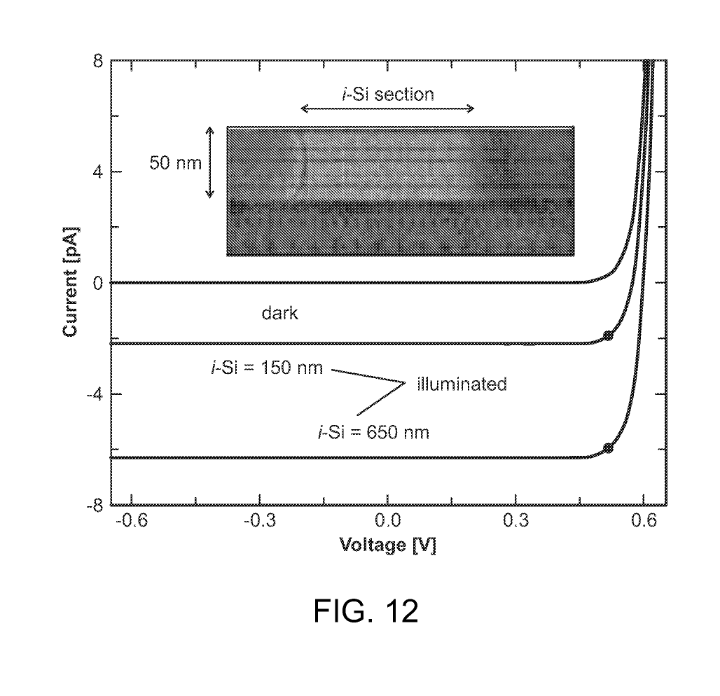

Excellent NiGe or NiSi ohmic contacts to LANL-grown heavily-doped nanowires have been obtained for certain embodiments, and the structures contained an epitaxial p⁺n⁺ contact. In one or more embodiments, the p⁺n⁺ contact is less than 100 or 200 nm in thickness and of doping density higher than 10¹⁹ cm⁻³ to ensure that it passes significant current Isc under small reverse bias (with minimum voltage drop). This contributes to device efficiency. In certain embodiments, the Isc values of the Si and Ge pin structures are closely matched to prevent the low Isc diode degrading the fill factor of the high Isc diode, as illustrated in FIG. 12 for two Si pin nanowire diodes with different i-Si regions simulated using Synopsys TCAD (Technology Computer-Aided Design) under 1 W/cm² illumination at X=500 nm. In certain embodiments, the total open-circuit voltage V_{OC} is the sum of the two pin V_{OC} values, and the resulting tandem structure with identical currents at the maximum power operating point significantly enhances the overall efficiency. In certain embodiments, modeling of Ge pin section requires an experimentally informed understanding of the approximate surface state densities and surface recombination rates in the oxide-passivated Ge material, which is known to be considerably less perfect than oxide-passivated Si. In certain embodiments, measurements on individual Si and Ge pin sections under solar illumination provide the design input for the hetero-nanowire growth.

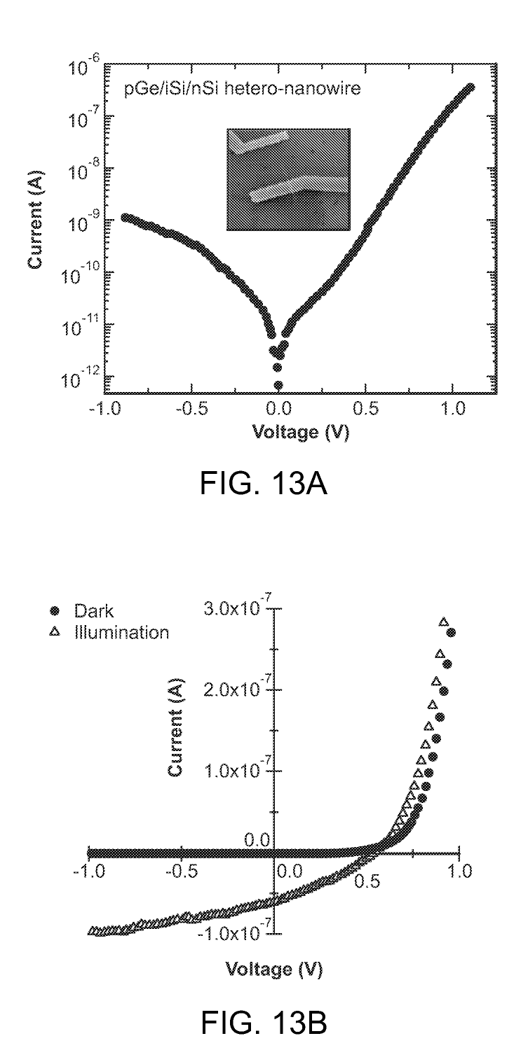

Optical measurements of Ge/Si pin NW junctions have been performed. These hetero-nanowires were intended for gate-controlled tunneling transistors and hence contained intrinsic i-Si (rather than i-Ge) regions, but they still provide experimental evidence for several necessary ingredients of the proposed structure. FIG. 13A shows the I(V) curves in the dark of a D˜40 nm Ge/Si axial pin junction (grown at LANL with in-situ junction doping by B2H6 and PH3, with doping densities of ˜1×10¹⁷ cm⁻³ on p-Ge side and ˜5×10¹⁸ cm³ on n-Si side of the junction) together with an SEM of the two-terminal device (inset). The doping and low resistance ohmic contacts to the device were confirmed by measurements on four-terminal devices from the same growth. The junction exhibited good rectification ratio of ˜10³ at moderate voltages. In general, the n-Si, i-Si, i-Ge, and p-Ge layers can be optimized in thickness for absorption efficiency. This optimization involves an inverse relationship between doping density and thickness (i.e. lower doping would require thicker layers to achieve equivalent efficiency).

The optically generated current under laser illumination (λ=532 nm) for the same Ge/Si hetero-nanowire is shown in FIG. 13B. Because of the low reverse-bias current in the dark, due to the relatively long i-Si wire section, the open-circuit V_{OC} of this Si/Ge hetero-nanowire is significant (˜0.54 V), underscoring the importance of proper design of the intrinsic region. Generated power is ˜16.2 nW, J_{SC}˜4×10³ A/cm² and power conversion efficiency is ˜1.6%, which is comparable to state-of-the-art values in reported single-NW solar cells. Several designs of tandem Ge/Si pin hetero-NWs have been grown.

While there have been shown and described examples of the present invention, it will be readily apparent to those skilled in the art that various changes and modifications may be made therein without departing from the scope of the invention.

1. A photodetector device comprising:
a photo-responsive layer;
wherein the photo-responsive layer comprises an insulator with embedded amorphous germanium quantum dots.

2. The device of claim 1 wherein the insulator comprises a metal oxide.

3. The device of claim 1 wherein germanium quantum dots are between below 20 nm in diameter.

4. The device of claim 1 wherein the photo-responsive layer comprises germanium quantum dots of density between 10¹⁷ and 10¹⁹ cm⁻³.

5. The device of claim 1 wherein the photo-responsive layer comprises a layer with a thickness less than 300 nm.

6. The device of claim 1, further comprising
a transparent conducting layer positioned over and in electrical communication with an upper surface of the photodetector device; and
a semiconductor substrate positioned under a lower surface of the photodetector device; and
an electrical contact in electrical communication with the semiconductor substrate;
wherein the quantum dots are in electrical communication with the substrate and the transparent conducting layer.

7. The device of claim 6 wherein the substrate comprises silicon.

8. The device of claim 6 wherein the transparent conducting layer comprises multiple layers.

9. The device of claim 6 wherein the transparent conducting layer comprises an anti-reflection coating.

10. The device of claim 6 wherein the transparent conducting layer comprises indium-zinc-oxide.

11. (canceled)

12. (canceled)

13. (canceled)

14. (canceled)

15. (canceled)

16. (canceled)

17. A nanowire solar cell device comprising:
a plurality of vertically aligned heterogeneous photo-responsive nanowires, at least one nanowire having a top surface in electrical communication with a first transparent electrical contact and a bottom surface in electrical communication with a second electrical contact; wherein the nanowires comprise:
a germanium-based axially stacked pin junction comprising a p-doped layer and an n-doped layer with an intrinsic layer in between the n- and p-doped regions, and a silicon-based axially stacked pin junction comprising a p-doped layer and an n-doped layer with an intrinsic layer in between the n- and p-doped regions and, wherein the p-doped layer of the silicon-based pin junction is positioned adjacent to the n-doped layer of the germanium-based axial pin junction.

18. The device of claim 17 comprising the multitude of heterogeneous semiconductor nanowires embedded in a transparent insulating layer wherein the top and bottom surfaces of the nanowire are exposed.

19. The device of claim 18 wherein the transparent insulating layer comprises a metal oxide.

20. The device of claim 17 wherein one or both of the electrical contacts comprise an transparent conductive oxide.

21. The device of claim 20 wherein the transparent oxide comprises indium-zinc-oxide.

22. The device of claim 17 comprising heterogeneous semiconductor nanowires of less than 300 nanometers in diameter.

23. The device of claim 17 comprising heterogeneous semiconductor nanowires of more than 5 microns in length.

24. The device of claim 17 comprising heterogeneous semiconductor nanowires tapered in diameter along at least a portion of its length, forming a wider tapered end and a narrower tapered end.

25. The device of claim 24 comprising the first electrical contact in electrical communication with the wider tapered end of the nanowire.

26. The device of claim 24 comprising the first electrical contact in electrical communication with the narrower tapered end of the nanowire.

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. A heterogeneous photo-responsive nanowire comprising:
a germanium-based axially stacked pin junction comprising a p-doped layer and an n-doped layer with an intrinsic layer in between the n- and p-doped regions, and
a silicon-based axially stacked pin junction comprising a p-doped layer and an n-doped layer with an intrinsic layer in between the n- and p-doped regions and, wherein the p-doped layer of the silicon-based pin junction is positioned adjacent to the n-doped layer of the germanium-based axial pin junction.
